(19) United States
(12) Patent Application Publication
(10) Pub. No.: US 2019/0056656 A1
(43) Pub. Date: Feb. 21, 2019

(54) METHOD FOR MAKING PAPER-BASED BIOSENSOR PATTERN

(71) Applicant: HON HAI PRECISION INDUSTRY CO., LTD., New Taipei (TW)

(72) Inventor: HSIU-WEN CHIEN, New Taipei (TW)

(21) Appl. No.: 15/692,353

(22) Filed: Aug. 31, 2017

(30) Foreign Application Priority Data
Aug. 17, 2017 (TW) 106128013

(51) Int. Cl. G03F 7/004; H05K 3/00

(52) U.S. Cl. CPC G03F 7/0045; G03F 7/16; H05K 3/0023

(57) ABSTRACT

A method of making paper-based biosensor pattern comprises a sheet of paper provided as a substrate, and coating a hydrophobic photoresist on the substrate as a coating layer. At least a portion of the coating layer is exposed to make the hydrophobic photoresist in one or more exposed areas become a hydrophilic structure. The hydrophobic photoresist in one or more covered/unexposed area remains hydrophobic, thereby defining a pattern of the paper-based biosensor.

### FIELD

The subject matter relates to a method for making a paper-based biosensor pattern.

### BACKGROUND

Paper-based biosensors can detect neurotoxins quickly and easily. A paper-based biosensor typically includes a substrate. To produce a paper-based biosensor, it is necessary to produce a hydrophobic pattern on the substrate through a photomask. The hydrophobic pattern can be used to divide the substrate into a first area for printing electrodes and a second zone for the reaction between the paper-based biosensor and the neurotoxins. However, the substrate usually has a three-dimensional cellulose network structure, thereby causing the non-patterned area to be hard to remove from the substrate. Thus, improvement in the art is needed.

### BRIEF DESCRIPTION OF THE DRAWING

Implementations of the present disclosure will now be described, by way of example only, with reference to the attached FIGURE.

FIG. 1 is a flowchart of a method for making a paper-based biosensor pattern.

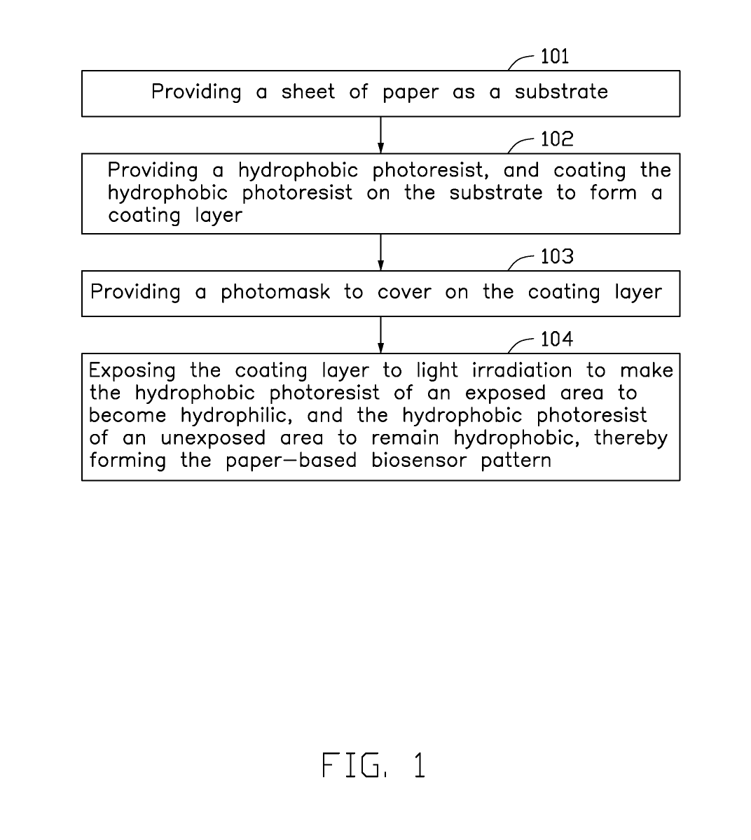

### DETAILED DESCRIPTION

It will be appreciated that for simplicity and clarity of illustration, where appropriate, reference numerals have been repeated among the different FIGURES to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details.

In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

One definition that applies throughout this disclosure will now be presented.

The term “substantially” is defined to be essentially conforming to the particular dimension, shape, or other feature that the term modifies, such that the component need not be exact. For example, “substantially rectangular” means that the object resembles a rectangle, but can have one or more deviations from a true rectangle.

The term “comprising,” when utilized, means “including, but not necessarily limited to”; it specifically indicates open-ended inclusion or membership in the so-described combination, assembly, series, and the like.

Referring to the FIGURE, a method for making a paper-based biosensor pattern is illustrated. The exemplary method is provided by way of example, as there are a variety of ways to carry out the method. Each block shown in the FIGURE represents one or more processes, methods, or subroutines, carried out in the exemplary method. Furthermore, the illustrated order of blocks is by example only, and the order of the blocks can change. Additional blocks may be added or fewer blocks may be utilized, without departing from this disclosure. The exemplary method can begin at block 101.

At block 101, a sheet of paper is provided as a substrate of the paper-based biosensor.

The substrate is a hydrophilic substance and has a three-dimensional network structure. The substrate comprises hydroxypropyl cellulose (HPC) having a chemical molecular structure of

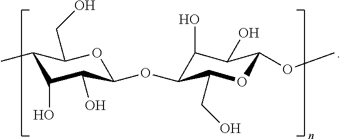

At block 102, a photoresist is provided, and the hydrophobic photoresist is coated on the substrate as a coating layer.

The photoresist is hydrophobic. In the exemplary embodiment, the photoresist is spiropyran (SP). The chemical molecular formula of the spiropyran is

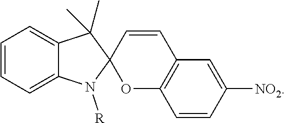

When exposed to ultraviolet irradiation, a benzene ring of the spiropyran is opened. The benzene ring of the spiropyran can be closed again when exposed to ultraviolet irradiation again or when heated. The chemical reaction of opening the benzene ring of the spiropyran after ultraviolet irradiation is shown as follows:

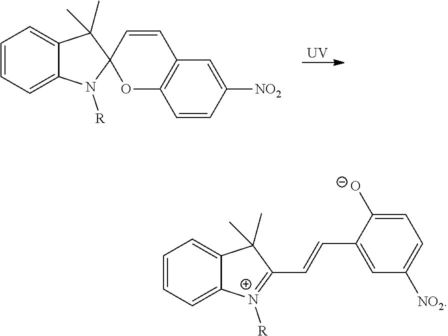

R of the spiropyran represents a carboxyl group (—COOH). That is, the spiropyran is 1′-(3-carboxyethyl)-3′, 3′-dimethyl-6-nitrospiro [indoline-2,2[2H] Pyran] (SPCOOH).

When the photoresist is SPCOOH, the photoresist and a catalyst are simultaneously coated on the substrate and placed at room temperature. The catalyst is N, N′-dicyclohexyl Carbodiimide (DCC) and 4-dimethylaminopyridine (DMAP). The SPCOOH and the HPC of the substrate can undergo an esterification reaction, thereby forming spiropyran hydroxypropyl cellulose (SP-HPC). The chemical reaction between the SPCOOH and the HPC is shown as follows:

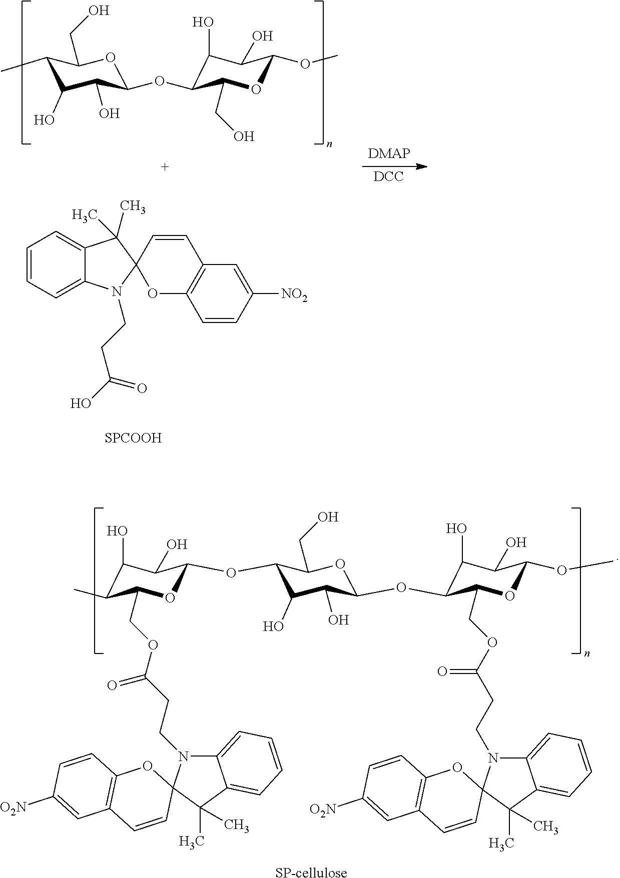

At block 103, a photomask is provided and covers the coating layer. The photomask comprises a predetermined pattern.

At block 104, the coating layer is exposed to ultraviolet light irradiation through the photomask, thereby causing the hydrophobic photoresist positioned in one or more exposed areas to become hydrophilic. The hydrophobic photoresist positioned in one or more unexposed areas remain hydrophobic, thus forming the paper-based biosensor pattern.

When exposed to ultraviolet irradiation, the benzene ring of the spiropyran (SP) of the exposed area is opened to form merocyanine (MC) with large conjugate structure. The SP after opening benzene ring is hydrophilic. The chemical reaction of SP opening bezene ring to form merocyanine (MC) with large conjugated structure is shown as follows:

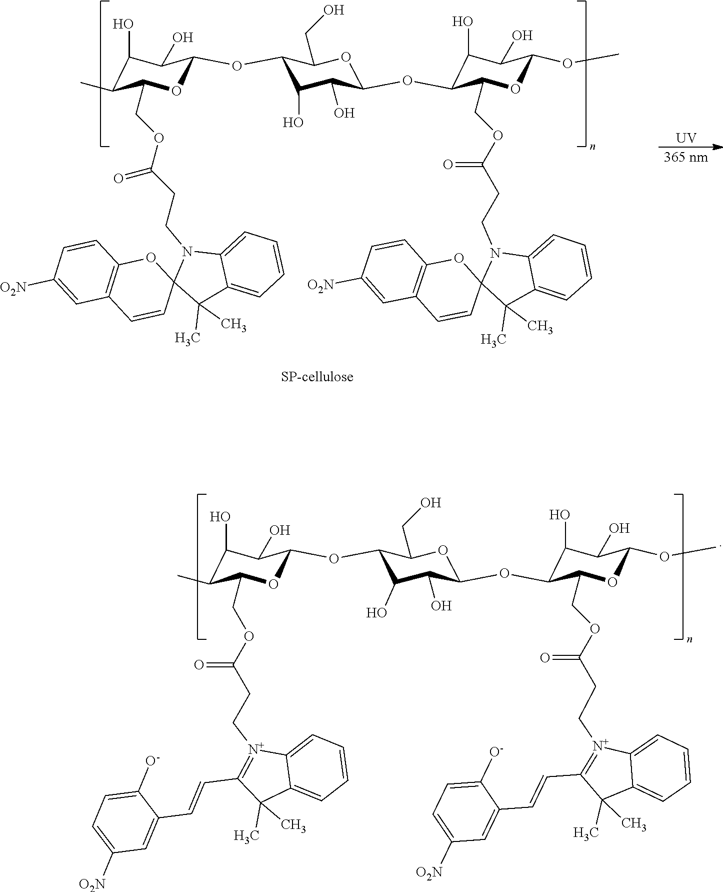

In other exemplary embodiments, the photoresist may be other hydrophobic substance which can be converted into a hydrophilic substance under ultraviolet light irradiation.

The hydrophilic group of the paper-based pattern can be dissolved in an aqueous solution. The removal process is relatively simple, the process for making the paper-based biosensor is simplified, and the time required can be decreased.

The embodiments shown and described above are only examples. Many details are often found in the art such as the other features. Therefore, many such details are neither shown nor described. Even though numerous characteristics and advantages of the present disclosure have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method of making a paper-based biosensor pattern comprising:
providing a sheet of paper as a substrate;
providing a hydrophobic photoresist, and coating the hydrophobic photoresist on the substrate to form a coating layer;
exposing the coating layer to light irradiation to make the hydrophobic photoresist in an exposed area to become hydrophilic, and the hydrophobic photoresist in an unexposed area to remain hydrophobic, thereby forming the paper-based biosensor pattern.

2. The method of claim 1, wherein the hydrophobic photoresist is spiropyran (SP).

3. The method of claim 2, wherein the substrate comprises hydroxypropyl cellulose, the spiropyran is 1′-(3-carboxyethyl)-3′, 3′-dimethyl-6-nitrospiro [indoline-2,2[2H] Pyran], the spiropyran and a catalyst are simultaneously coated on the substrate, thereby causing the 1′-(3-carboxyethyl)-3′, 3′-dimethyl-6-nitrospiro [indoline-2,2[2H] Pyran] and the hydroxypropyl cellulose to undergo an esterification reaction to form a spiropyran hydroxypropyl cellulose.

4. The method of claim 3, wherein the catalyst is N, N′-dicyclohexyl Carbodiimide and 4-dimethylaminopyridine.

5. The method of claim 2, wherein a benzene ring of the SP of the exposed area is open to become a merocyanine (MC) large conjugate structure.

6. The method of claim 5, wherein the benzene ring of the spiropyran is closed again when exposed to light irradiation again.

7. The method of claim 5, wherein the benzene ring of the spiropyran is closed again when heated.

8. The method of claim 1, wherein the substrate has a three-dimensional network structure.

9. The method of claim 1, further comprising:
providing a photomask to cover the coating layer;
wherein the coating layer is exposed to light radiation through the photomask.

10. The method of claim 1, wherein the light irradiation is ultraviolet irradiation.
